(19) United States
(12) Patent Application Publication
(10) Pub. No.: US 2025/0119123 A1
(43) Pub. Date: Apr. 10, 2025

(54) RADIO FREQUENCY SWITCH AND METHOD FOR OPERATING THEREOF

(71) Applicant: SAMSUNG ELECTRO-MECHANICS CO., LTD., Suwon-si (KR)

(72) Inventors: Byeonghak JO, Suwon-si (KR); Wonsun HWANG, Suwon-si (KR); Shinhaeng HEO, Suwon-si (KR); Dongil KANG, Suwon-si (KR)

(73) Assignee: SAMSUNG ELECTRO-MECHANICS CO., LTD., Suwon-si (KR)

(21) Appl. No.: 18/603,949

(22) Filed: Mar. 13, 2024

(30) Foreign Application Priority Data
Oct. 6, 2023 (KR) 10-2023-0133130

(51) Int. Cl. H03K 3/012; H03K 17/56

(52) U.S. Cl. CPC H03K 3/012; H03K 17/56

(57) ABSTRACT

A radio frequency (RF) switch circuit and a method for operation of a RF switch circuit. The RF switch circuit may include a first switch connected between a first port and an antenna port, a second switch connected between a second port and the antenna port, a third switch connected between the antenna port and ground, a fourth switch connected between the antenna port and the ground, and a switch control circuit configured to control the first switch, the second switch, and the third switch to be turned off and the fourth switch to be turned on in a low power mode.

### CROSS-REFERENCE TO RELATED APPLICATIONS

This application claims the benefit under 35 USC 119(a) of Korean Patent Application No. 10-2023-0133130 filed on Oct. 6, 2023, in the Korean Intellectual Property Office, the entire disclosure of which is incorporated herein by reference for all purposes.

### BACKGROUND

### 1. Field

This disclosure relates to a radio frequency (RF) switch circuit and method for operating thereof.

### 2. Description of the Background

In a wireless communication system, a RF switch inside a front end module (FEM) may be located at the end of the FEM and may be placed close to an antenna.

In a wireless communication system that supports multi-mode multi-band, multiple FEMs may share one antenna, and as integration increases, the isolation characteristics between antennas worsen, thus signals are transmitted to adjacent antennas, and a radiated spurious emission (RSE) may be generated from an RF switch connected to an adjacent antenna or an RF switch inside the FEM.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a radio frequency (RF) switch circuit includes a first switch connected between a first port and an antenna port, a second switch connected between a second port and the antenna port, a third switch connected between the antenna port and ground, a fourth switch connected between the antenna port and the ground, and a switch control circuit configured to control the first switch, the second switch, and the third switch to be turned off and the fourth switch to be turned on in a low power mode.

The switch control circuit may be configured to turn on the third switch and turn off the first switch, the second switch, and the fourth switch in an isolation mode.

The switch control circuit may include a first driver configured to select one of a first voltage and a second voltage generated from a first power source according to a first control signal and output the selected voltage to the first switch, a second driver configured to select one of the first voltage and the second voltage according to the first control signal and output the selected voltage to the second switch, a third driver configured to select one of the first voltage and the second voltage according to the first control signal and output the selected voltage to the third switch, and a fourth driver configured to output one of a third voltage generated from a second power source different from the first power source and a fourth voltage generated from the first power source to the fourth switch according to a second control signal.

The second control signal may include the first voltage, and the first voltage may be set to 0V in the low power mode.

The switch control circuit further may include a low dropout (LDO) circuit configured to generate the first voltage from the first power source, and a charge pump circuit configured to generate the second voltage lower than the first voltage from the first voltage.

The third voltage may be lower than the first voltage, and the second power source may be a continuous power source.

The fourth driver may include a first transistor configured to provide the third voltage as a turn-on voltage to the fourth switch through an output terminal, wherein the first transistor may have a control terminal that receives the second control signal, and a second transistor configured to provide the fourth voltage as a turn-off voltage to the fourth switch through the output terminal, wherein the second transistor may have a control terminal connected to ground.

The fourth driver may further include a third transistor connected between the first transistor and the output terminal, wherein the third transistor may have a control terminal connected to ground, and may be configured to be turned on when the first transistor is turned on, and a fourth transistor connected between the second transistor and the output terminal, wherein the fourth transistor may have a control terminal connected to ground, and may be configured to be turned on when the second transistor is turned on.

The switch control circuit may be configured to turn on the first switch and turn off the second switch, the third switch and the fourth switch in a reception mode, and to turn on the second switch and turn off the first switch, the third switch, and the fourth switch in a transmission mode.

In another general aspect, a method of operating a radio frequency (RF) switch circuit includes turning on a first switch connected between a first port and an antenna port to receive a signal from the antenna port in a reception mode, turning off the first switch and turning on a second switch connected between a second port and the antenna port to transmit a signal to the antenna port in a transmission mode, turning off the first switch and the second switch and turning on a third switch connected between the antenna port and ground to terminate the antenna port in isolation mode, and turning off the first switch, the second switch, and the third switch, and turning on a fourth switch connected between the antenna port and the ground to terminate the antenna port in a low power mode.

The method may further include turning off the fourth switch in the isolation mode.

The method may further include turning on or off the first switch, the second switch, and the third switch, respectively by providing one of a first voltage and a second voltage generated from a first power source to the first switch, and the second switch, and the third switch, respectively, according to a first control signal, and turning on or off the fourth switch by providing one of a third voltage generated from a second power source different from the first power source and a fourth voltage generated from the first power source according to a second control signal.

The second control signal may include the first voltage, and the first voltage may be set to 0V in the low power mode.

The third voltage may be lower than the first voltage.

In another general aspect, a radio frequency (RF) switch circuit includes a first switch connected between a first port and an antenna port, a second switch connected between a second port and the antenna port, a third switch connected between the antenna port and ground, a fourth switch connected between the antenna port and the ground, and a switch control circuit configured to control the first switch, the second switch, and the third switch to be turned off using a first power source and the fourth switch to be turned on using a second power source different from the first power source in a low power mode.

The switch control circuit may be configured to turn off the first switch, the second switch, and the fourth switch and turn on the third switch using the first power source in an isolation mode.

The switch control circuit may be configured to turn on the first switch and turn off the second switch, the third switch, and the fourth switch using the first power source in a reception mode.

The switch control circuit may be configured to turn on the second switch and turn off the first switch, the third switch, and the fourth switch using the first power source in a transmission mode.

The switch control circuit may include a first driver configured to select one of a first voltage and a second voltage generated from the first power source according to a first control signal and output the selected voltage to the first switch, a second driver configured to select one of the first voltage and the second voltage according to the first control signal and output the selected voltage to the second switch, a third driver configured to select one of the first voltage and the second voltage according to the first control signal and output the selected voltage to the third switch, and a fourth driver configured to output one of a third voltage generated from the second power source and a fourth voltage generated from the first power source to the fourth switch according to a second control signal.

Other features and aspects will be apparent from the following detailed description, the drawings, and the claims.

### BRIEF DESCRIPTION OF THE DRAWINGS

FIG. 1 and FIG. 2 are diagrams showing an example of an RF switch used in a wireless communication system.

FIG. 3 is a diagram showing an example of the FEM shown in FIG. 1 or FIG. 2.

FIG. 4 is a diagram showing an example of an RF switch circuit according to an embodiment.

FIG. 5 is a diagram showing the state of each switch in the operation mode of the RF switch circuit shown in FIG. 4.

FIG. 6 is a diagram showing an example of the switch control circuit shown in FIG. 4.

FIG. 7 is a diagram showing the control signal of the driver 117 and the operation state of the charge pump circuit according to the operation mode of the RF switch circuit shown in FIG. 4.

FIG. 8 is a diagram showing an example of the switch control circuit shown in FIG. 4.

FIG. 9 is a circuit diagram of the driver 115 shown in FIG. 5.

FIG. 10 is a diagram showing an example of an RF switch circuit according to another embodiment.

FIG. 11 is a diagram showing the state of each switch in the operation mode of the RF switch circuit shown in FIG. 10.

FIG. 12 is a diagram showing an example of the control signal of the driver 115 according to the operation mode of the RF switch circuit shown in FIG. 10.

FIG. 13 is a circuit diagram of the driver 117 shown in FIG. 5.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more of the embodiments may provide an RF switch circuit and a method for operating thereof that may reduce a radiated spurious emission (RSE).

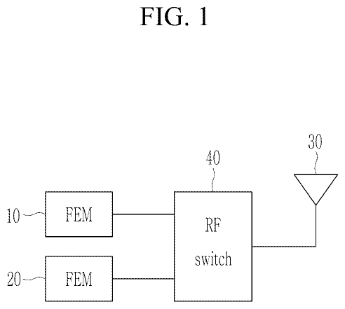

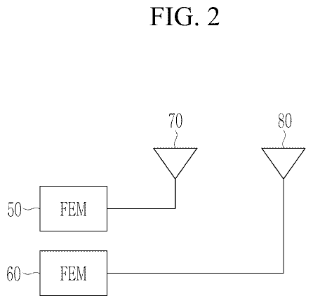

FIG. 1 and FIG. 2 are diagrams showing an example of an RF switch used in a wireless communication system.

Referring to FIG. 1, in a communication system, a plurality of front end modules (FEMs) 10 and 20 may be connected to one antenna 30.

The RF switch 40 may connect one FEM among the plurality of FEMs 10 and 20 to the antenna 30.

Unlike FIG. 1, referring to FIG. 2, a plurality of FEMs 50 and 60 may be connected to a plurality of antennas 70 and 80, respectively.

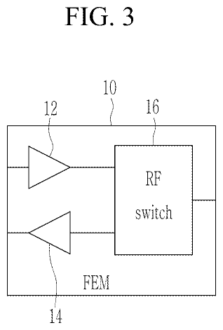

FIG. 3 is a diagram showing an example of the FEM shown in FIG. 1 or FIG. 2. Although FEM 10 shown in FIG. 1 is shown in FIG. 3, the FEM 20 shown in FIG. 1 or the FEMs 10 and 20 shown in FIG. 2 may also be configured the same or similar to FEM 10 shown in FIG. 3.

Referring to FIG. 3, the FEM 10 may include a power amplifier (PA) 12, a low noise amplifier (LNA) 14, and an RF switch 16.

The RF switch 16 may select connection with either PA 12 or LNA 14.

In a wireless communication system supporting multi-mode multi-band, some of the multiple FEMs may share one antenna as shown in FIG. 1, and some of the multiple FEMs may each be connected to different antennas. Since multiple FEMs and multiple antennas with these connection structures are integrated, a signal transmitted from any one antenna may be transmitted to adjacent antennas, and a radiated spurious emission (RSE) may be induced in and transmitted in the RF switches connected to the adjacent antennas or in the RF switch inside the FEM. Therefore, the antenna port connected to the RF switch may be designed to maintain 50 Ohm in all cases.

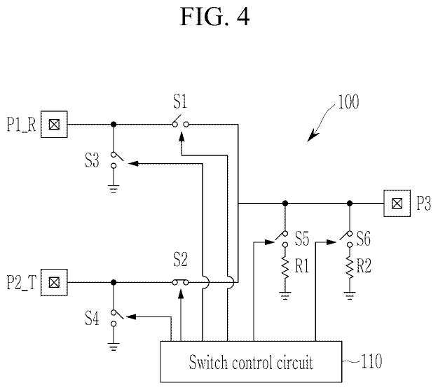

FIG. 4 is a diagram showing an example of an RF switch circuit according to an embodiment.

Referring to FIG. 4, the RF switch circuit 100 may include a port P1_R, a port P2_T, a port P3, a switch S1, a switch S2, a switch S3, a switch S4, and a switch S5, and a switch S6. The RF switch circuit 100 may further include a resistor R1 and a resistor R2. The RF switch circuit 100 may further include a switch control circuit 110.

The port P1_R may be a reception port. The port P2_T may be a transmission port. A path between the port P3 and the port P1_R may be a reception path. A path between the port P3 and the port P2_T may be a transmission path. The port P3 may be an output port or an antenna port for connection to an antenna.

The switch S1 may be connected between port P1_R and port P3. The switch S3 may be connected between port P1_R and ground. The switch S1 and switch S3 may operate complementary. When the switch S1 is turned on, the switch S3 may be turned off, and when the switch S1 is turned off, the switch S3 may be turned on.

The switch S2 may be connected between port P2_T and port P3. The switch S4 may be connected between port P2_T and ground. The switch S2 and switch S4 may operate complementary. When the switch S2 is turned on, the switch S4 may be turned off, and when the switch S2 is turned off, the switch S4 may be turned on.

The switch S5 may be connected between port P3 and ground. The resistor R1 may be connected between the switch S5 and ground.

The switch S6 may be connected between port P3 and ground. The resistor R2 may be connected between the switch S6 and ground.

In low power mode, switches S1 to S5 may be turned off and switch S6 may be turned on. In low power mode, the RF switch circuit 100 may minimize current consumption by disabling almost all internal circuit elements. However, only the switch S6 may be turned on and the port P3 may be terminated at 50 ohms.

The switch S1, the switch S2, the switch S3, the switch S4, the switch S5, and the switch S6 may be turned on or off according to a control signal output from the switch control circuit 110.

The switch control circuit 110 may control turning on and off of the switch S1, the switch S2, the switch S3, the switch S4, the switch S5, and the switch S6 according to an operation mode of the RF switch circuit 100.

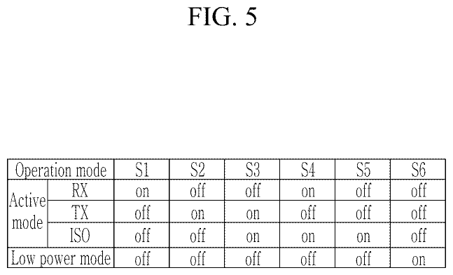

FIG. 5 is a diagram showing the state of each switch in the operation mode of the RF switch circuit shown in FIG. 4.

Referring to FIG. 5, an operation mode of the RF switch circuit 100 may include an active mode and a low power mode.

The active modes may include a reception mode RX, a transmission mode TX, and an isolation mode ISO.

In the reception mode RX, the switch S1 and the switch S4 may be turned on, and the switch S2, the switch S3, the switch S5, and the switch S6 may be turned off. Accordingly, the signal received through the port P3 may be output through the port P1_R.

In transmission mode TX, the switch S2 and the switch S3 may be turned on, and the switch S1, the switch S4, the switch S5, and the switch S6 may be turned off. Accordingly, the signal input through the port P2_T may be output to the port P3.

In isolation mode ISO, the switch S3, the switch S4, and the switch S5 may be turned on, and the switch S1, the switch S2, and the switch S6 may be turned off. Accordingly, the isolation between the transmission path and the reception path may be increased when there is no signal transmission or reception.

In low power mode, the switches S1 to S5 may be turned off and the switch S6 may be turned on. Accordingly, the port P3 may be terminated at 50 ohms in low power mode.

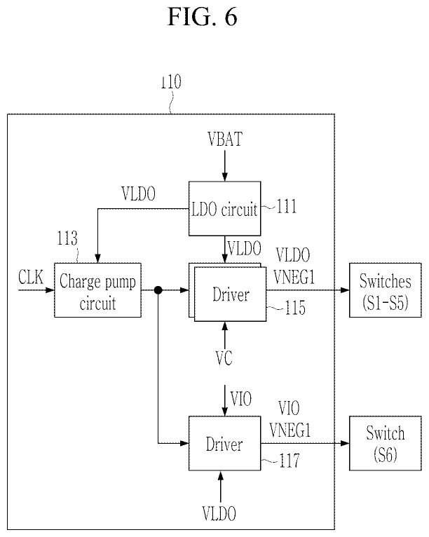

FIG. 6 is a diagram showing an example of the switch control circuit shown in FIG. 4.

Referring to FIG. 6, the switch control circuit 110 may control the switches S1 to S6 shown in FIG. 4.

The switch control circuit 110 may include a low dropout (LDO) circuit 111, a charge pump circuit 113, and a plurality of drivers 115 that control the switches S1 to S5, and a driver 117 that controls the switch S6.

The LDO circuit 111 may generate a positive voltage VLDO lower than a battery voltage VBAT from the battery voltage VBAT supplied from a battery power, and may provide the positive voltage VLDO to the plurality of drivers 115 and the driver 117. Additionally, the LDO circuit 111 may provide the voltage VLDO to the charge pump circuit 113. The positive voltage VLDO may be a voltage higher than the turn-on voltage of the switches S1 to S5.

The charge pump circuit 113 may generate a negative voltage VNEG1 by charge pumping the voltage VLDO according to the input clock signal CLK, and may provide the negative voltage VNEG1 to the plurality of drivers 115 and the driver 117.

The plurality of drivers 115 may generate a control signal having the positive voltage VLDO or the negative voltage VNEG1 according to a control signal VC input from the outside and may provide the control signal to the switches S1 to S5, respectively.

The driver 117 may receive the positive voltage VLDO provided from the LDO circuit 111 as a control signal, may generate a control signal having a positive voltage VIO or the negative voltage VNEG1, and may provide it to the switch S6. The driver 117 may generate a control signal that turns on the switch S6 when the switches S1 to S5 are turned off in the low power mode. The driver 117 may generate a control signal that turns on the switch S6 when the voltage VLDO becomes 0V. Here, the positive voltage VIO is a voltage supplied from a continuous power source different from the battery voltage VBAT and may be lower than the voltage VLDO. Since current consumption must be minimized in low power mode, the driver 117 may control the switch S6 using the positive voltage VIO.

According to an embodiment, the switch S6 may be turned on at a lower voltage than voltages applied to the switches S1 to S5. The switch S6 may be turned on by the positive voltage VIO to reduce current consumption. For example, the turn-on voltage of the switches S1 to S5 may be 2.5V, and the turn-on voltage of the switch S6 may be 1.8V, which is lower than 2.5V. Meanwhile, if the low turn-on voltage may be used, the on-resistance of the corresponding switch S6 may increase. Accordingly, the resistance value of the resistor R2 connected to the switch S6 may be set according to the on-resistance of the switch S6. According to an embodiment, the resistance value of the resistor R2 may be set to a value that optimizes the performance of the RSE reduction when the switch S6 is turned on.

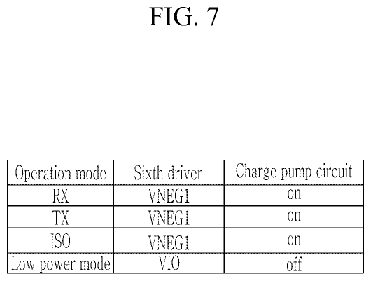

FIG. 7 is a diagram showing the control signal of the driver 117 and the operation state of the charge pump circuit according to the operation mode of the RF switch circuit shown in FIG. 4. In FIG. 7, the sixth driver may represent driver 117.

Referring to FIG. 7, the charge pump circuit 113 may be set to the on state in the active mode and may be set to the off state in the low power mode.

In the reception mode RX of the active mode, the driver 117 may output the negative voltage VNEG1 as a control signal to turn off the switch S6.

In transmission mode TX of the active mode, the driver 117 may output a negative voltage VNEG1 as a control signal to turn off the switch S6.

In the isolation mode ISO of the active mode, the driver 117 may output a negative voltage VNEG1 as a control signal to turn off the switch S6. Meanwhile, in the isolation mode ISO of the active mode, the switch S5 is turned on, so the signal input through the port P3 may be terminated to ground through the switch S5.

In the low power mode, the driver 117 may output the positive voltage VIO as a control signal to turn on the switch S6. At this time, the switches S1 to S5 may be turned off.

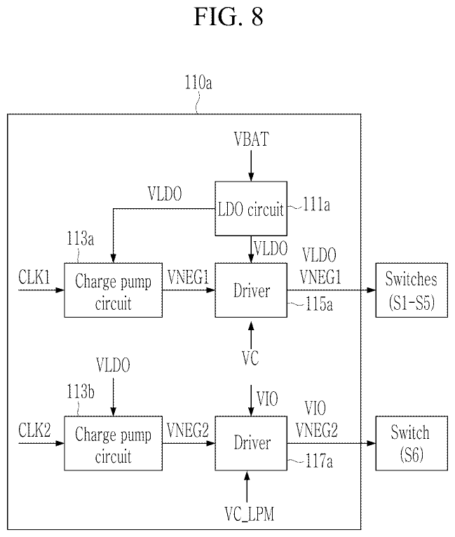

FIG. 8 is a diagram showing an example of the switch control circuit shown in FIG. 4.

As shown in FIG. 8, the turn-off voltage of switch S6 may be different from the turn-off voltage of switches S1 to S5. For example, the turn-off voltage of the switch S6 may be a negative voltage VNEG2, and the turn-off voltage of the switches S1 to S5 may be a negative voltage VNEG1.

In this case, unlike FIG. 6, the switch control circuit 110a may include a charge pump circuit 113a that generates the negative voltage VNEG1 and a charge pump circuit 113b that generates the negative voltage VNEG2.

The charge pump circuit 113a may generate the negative voltage VNEG1 by charge pumping the voltage VLDO according to the clock signal CLK1, and may provide the negative voltage VNEG1 to a plurality of drivers 115a that provide control signals to the switches S1 to S5.

The charge pump circuit 113b may generate the negative voltage VNEG2 by charge pumping the voltage VLDO according to the clock signal CLK2, and may provide the negative voltage VNEG2 to the driver 117a. The clock signal CLK2 may be the same as or different from the clock signal CLK1.

The plurality of drivers 115a may each generate a control signal having the positive voltage VLDO or the negative voltage VNEG1 according to a control signal VC input from the outside and may provide the generated control signal to the switches S1 to S5.

The driver 117a may generate a control signal having the positive voltage VIO or the negative voltage VNEG2 according to a control signal VC_LPM input from the outside and may provide the generated control signal to the switch S6. The control signal VC may be a control signal indicating one of the reception mode RX, transmission mode TX, and isolation ISO of the active mode. The control signal VC_LPM may be a control signal indicating a low power mode.

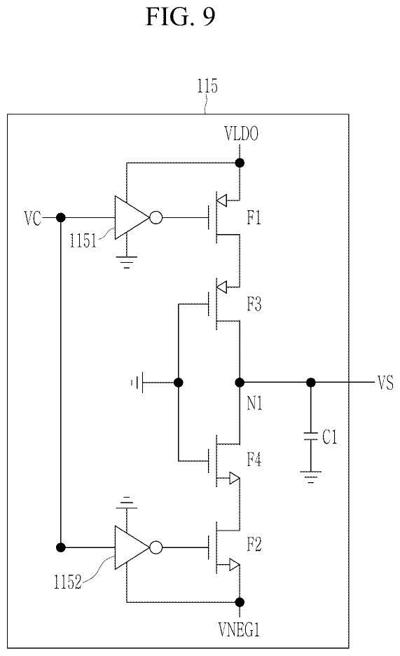

FIG. 9 is a circuit diagram of a driver 115 of the plurality of drivers 115 shown in FIG. 6.

Referring to FIG. 9, the driver 115 may include a transistor F1, a transistor F2, a transistor F3, a transistor F4, an inverter 1151, an inverter 1152, and a capacitor C1.

The transistor F1 may be a P-type FET, and transistor F2 may be an N-type FET. The transistor F3 may be the same type of FET as transistor F1, and the transistor F4 may be the same type of FET as transistor F2.

The positive voltage VLDO may be applied to the source terminal of the transistor F1 from the LDO circuit 111, the drain terminal of the transistor F1 may be connected to the source terminal of the transistor F3, and the drain terminal of the transistor F3 may be connected to a node N1.

The negative voltage VNEG1 may be applied to the source terminal of the transistor F2, the drain terminal of the transistor F2 may be connected to the source terminal of the transistor F4, and the drain terminal of the transistor F4 may be connected to the node N1. The gate terminal of transistor F3 and the gate terminal of transistor F4 may be connected to ground. The node N1 may be an output terminal of the driver 115.

The inverter 1151 may include an input terminal and an output terminal. The control signal VC may be input to the input terminal of the inverter 1151, and the output terminal of the inverter 1151 may be connected to the gate terminal of the transistor F1. The inverter 1151 may output a positive voltage VLDO or 0V to the output terminal depending on the control signal VC.

The inverter 1152 may include an input terminal and an output terminal. The control signal VC may be input to the input terminal of the inverter 1152, and the output terminal of the inverter 1152 may be connected to the gate terminal of the transistor F2. The inverter 1152 may output 0V or a negative voltage VNEG1 to the output terminal depending on the control signal VC.

When the control signal VC is at a high level (e.g., a positive voltage), the transistor F1 may be turned on and the transistor F2 may be turned off. When the transistor F1 is turned on, the voltage difference between the gate terminal and the source terminal of the transistor F3 becomes a negative voltage, so the P-type transistor F3 may be turned on and the positive voltage VLDO may be output as the control signal VS. The switches S1 to S5 may be turned on in response to the control signal VS having the positive voltage VLDO.

Meanwhile, when the control signal VC is at a low level (e.g., 0V), the transistor F1 may be turned off and the transistor F2 may be turned on. When the transistor F2 is turned on, the voltage difference between the gate terminal and the source terminal of the transistor F4 becomes a positive voltage, so the N-type transistor F4 may be turned on and the negative voltage VNEG1 may be output as the control signal VS. The switches S1 to S5 may be turned off in response to the control signal VS having the negative voltage VNEG1.

The capacitor C1 may be connected between the node N1 and ground and may serve to stabilize the voltage of the node N1.

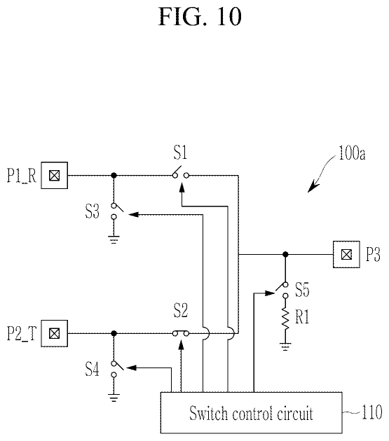

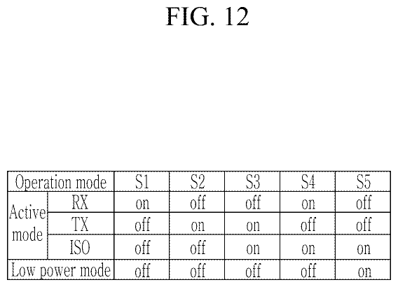

According to an embodiment, the switch S5 may be connected between port P3 and ground, and switch S6 may also be connected between port P3 and ground. Unlike the embodiment, as shown in FIG. 10, if only the switch S5 exists, the control signal of the driver 115 that controls the switch S5 according to the operation mode of the RF switch circuit may be output as shown in FIG. 12.

FIG. 10 is a diagram showing an example of an RF switch circuit according to another embodiment, and FIG. 12 is a diagram showing the state of each switch in the operation mode of the RF switch circuit shown in FIG. 10.

As shown in FIG. 10, the RF switch circuit 100a may have a structure without the switch S6. That is, only the switch S5 may be connected between the port P3 and ground.

As shown in FIG. 12, the RF switch circuit 100a may turn on the switches S1 and S4 and may turn off the switches S2, S3, and S5, in the reception mode RX. Accordingly, the signal received through the port P3 may be output through the port P1_R.

The RF switch circuit 100a may turn on the switches S2 and S3 and turn off the switches S1, S4, and S5, in the transmission mode TX. Accordingly, the signal input through the port P2_T may be output to the port P3.

The RF switch circuit 100a may turn on the switches S3, S4, and S5 and turn off the switches S1 and S2, in the isolation mode ISO. Accordingly, the isolation between the transmission path and the reception path may be increased when there is no signal transmission or reception.

The RF switch circuit 100a may turn off the switches S1 to S4 and turn on the switch S5 in a low power mode. Accordingly, the port P3 may be terminated at 50 ohms in the low power mode.

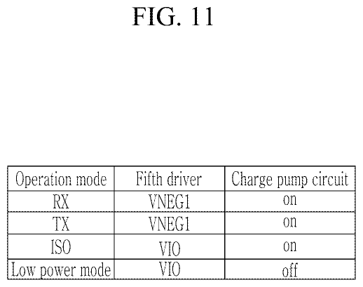

FIG. 11 is a diagram showing an example of the control signal of the driver 115 according to the operation mode of the RF switch circuit shown in FIG. 10.

Referring to FIG. 12, since the switch S5 is turned on in the isolation mode ISO of the active mode and the low power mode, the driver 115 that controls the switch S5 may output the positive voltage VLDO as a control signal to turn on the switch S5 in the isolation mode ISO of the active mode, and may output the positive voltage VLDO as a control signal to turn on the switch S5 even in the low power mode. In FIG. 11, the fifth driver may represent the driver 115 that controls the switch S5.

In the low power mode, the charge pump circuit 113 has off state, so the voltage of the source terminal of the transistor F2 has an undefined voltage value rather than the negative voltage VNEG1. For example, if the voltage of the source terminal of the transistor F2 is higher than 0V in the low power mode, leakage current may flow to the ground of the inverter 1152. This makes it impossible to meet the current specifications of the low power mode.

Therefore, according to the embodiment, in order to prevent leakage current of the inverter 1152 in the low power mode, the RF switch circuit 100 may further include the switch S6 connected between the port P3 and ground as shown in FIG. 4.

As also described, the switch S6 may be turned on with the positive voltage VIO that is lower than the positive voltage VLDO to minimize current consumption in the low power mode.

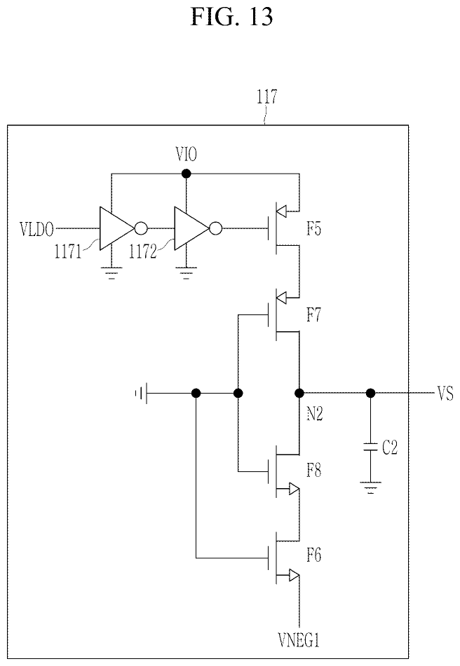

FIG. 13 is a circuit diagram of the driver 117 shown in FIG. 6.

Referring to FIG. 13, the driver 117 may include a transistor F5, a transistor F6, a transistor F7, a transistor F8, an inverter 1171, an inverter 1172, and a capacitor C2.

The transistor F5 may be a P-type FET, and the transistor F6 may be an N-type FET. The transistor F7 may be the same type of FET as transistor F5, and the transistor F8 may be the same type of FET as transistor F6.

A positive voltage VIO, which is a continuous power source, may be applied to the source terminal of the transistor F5, the drain terminal of the transistor F5 may be connected to the source terminal of the transistor F7, and the drain terminal of the transistor F7 may be connected to the node N2.

A negative voltage VNEG1 may be applied to the source terminal of the transistor F6, the drain terminal of the transistor F6 may be connected to the source terminal of the transistor F8, and the drain terminal of the transistor F8 may be connected to the node N2. The gate terminal of transistor F7 and the gate terminal of transistor F8 may be connected to ground. The node N2 may be an output terminal of the driver 117.

The inverter 1171 may include an input terminal and an output terminal.

The inverter 1172 may include an input terminal and an output terminal.

A voltage VLDO may be input as a control signal to the input terminal of the inverter 1171, and the output terminal of the inverter 1171 may be connected to the input terminal of the inverter 1172. The output terminal of the inverter 1172 may be connected to the gate terminal of the transistor F5. The inverters 1171 and 1172 may output a positive voltage VIO or 0V to the output terminal depending on the signal input to the input terminal.

When the voltage VLDO is 0V, that is, in low power mode, the transistor F5 may be turned on. Since the charge pump circuit 113 is turned off in the low power mode, the voltage of the source terminal of the transistor F6 has an undefined voltage value rather than the negative voltage VNEG1. Accordingly, the transistor F6 may be turned off. When the transistor F5 is turned on, the voltage difference between the gate terminal and the source terminal of the transistor F7 becomes a negative voltage, so the P-type transistor F7 may be turned on and the positive voltage VIO may be output as the control signal VS. The switch S6 may be turned on in response to the control signal VS having the positive voltage VIO. That is, switch S6 may be turned on in low power mode.

When the voltage VLDO is a positive voltage, that is, in active mode, the transistor F5 may be turned off, and the voltage difference between the gate terminal and the source terminal of the transistor F6 becomes a positive voltage, so the N-type transistor F6 may be turned on. When the transistor F6 is turned on, the voltage difference between the gate terminal and the source terminal of the transistor F8 becomes a positive voltage, so the N-type transistor F8 may be also turned on and the negative voltage VNEG1 may be output as the control signal VS. The switch S6 may be turned off in response to the control signal VS having the negative voltage VNEG1. That is, in active mode, the switch S6 may be turned off.

The capacitor C2 may be connected between the node N2 and ground, and may serve to stabilize the voltage of the node N2.

According to at least one of the embodiments, by improving the isolation characteristics between antennas in a wireless communication system supporting multi-band multi-mode, RSE caused by signals being transmitted to adjacent antennas may be reduced.

According to at least one of the embodiments, the current specification of a low power mode can be satisfied by preventing leakage current in the low power mode of the RF switch circuit.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A radio frequency (RF) switch circuit comprising:
a first switch connected between a first port and an antenna port;
a second switch connected between a second port and the antenna port;
a third switch connected between the antenna port and ground;
a fourth switch connected between the antenna port and the ground; and
a switch control circuit configured to control the first switch, the second switch, and the third switch to be turned off and the fourth switch to be turned on in a low power mode.

2. The RF switch circuit of claim 1, wherein
the switch control circuit is configured to turn on the third switch and turn off the first switch, the second switch, and the fourth switch in an isolation mode.

3. The RF switch circuit of claim 2, wherein
the switch control circuit comprises:
a first driver configured to select one of a first voltage and a second voltage generated from a first power source according to a first control signal and output the selected voltage to the first switch;
a second driver configured to select one of the first voltage and the second voltage according to the first control signal and output the selected voltage to the second switch;
a third driver configured to select one of the first voltage and the second voltage according to the first control signal and output the selected voltage to the third switch; and
a fourth driver configured to output one of a third voltage generated from a second power source different from the first power source and a fourth voltage generated from the first power source to the fourth switch according to a second control signal.

4. The RF switch circuit of claim 3, wherein
the second control signal includes the first voltage, and
the first voltage is set to 0V in the low power mode.

5. The RF switch circuit of claim 3, wherein
the switch control circuit further comprises:
a low dropout (LDO) circuit configured to generate the first voltage from the first power source; and
a charge pump circuit configured to generate the second voltage lower than the first voltage from the first voltage.

6. The RF switch circuit of claim 3, wherein
the third voltage is lower than the first voltage, and
the second power source is a continuous power source.

7. The RF switch circuit of claim 3, wherein
the fourth driver comprises:
a first transistor configured to provide the third voltage as a turn-on voltage to the fourth switch through an output terminal, wherein the first transistor has a control terminal that receives the second control signal; and
a second transistor configured to provide the fourth voltage as a turn-off voltage to the fourth switch through the output terminal, wherein the second transistor has a control terminal connected to ground.

8. The RF switch circuit of claim 7, wherein
the fourth driver further comprises:
a third transistor connected between the first transistor and the output terminal, wherein the third transistor has a control terminal connected to ground, and is configured to be turned on when the first transistor is turned on; and
a fourth transistor connected between the second transistor and the output terminal, wherein the fourth transistor has a control terminal connected to ground, and is configured to be turned on when the second transistor is turned on.

9. The RF switch circuit of claim 1, wherein
the switch control circuit is configured to turn on the first switch and turn off the second switch, the third switch and the fourth switch in a reception mode, and turn on the second switch and turn off the first switch, the third switch, and the fourth switch in a transmission mode.

10. A method of operating a radio frequency (RF) switch circuit, the method comprising:
turning on a first switch connected between a first port and an antenna port to receive a signal from the antenna port in a reception mode;
turning off the first switch and turning on a second switch connected between a second port and the antenna port to transmit a signal to the antenna port in a transmission mode;
turning off the first switch and the second switch and turning on a third switch connected between the antenna port and ground to terminate the antenna port in isolation mode; and
turning off the first switch, the second switch, and the third switch, and turning on a fourth switch connected between the antenna port and the ground to terminate the antenna port in a low power mode.

11. The method of claim 10, further comprising:
turning off the fourth switch in the isolation mode.

12. The method of claim 10, further comprising:
turning on or off the first switch, the second switch, and the third switch, respectively by providing one of a first voltage and a second voltage generated from a first power source to the first switch, the second switch, and the third switch, respectively, according to a first control signal; and
turning on or off the fourth switch by providing one of a third voltage generated from a second power source different from the first power source and a fourth voltage generated from the first power source according to a second control signal.

13. The method of claim 12, wherein
the second control signal includes the first voltage, and
the first voltage is set to 0V in the low power mode.

14. The method of claim 12, wherein
the third voltage is lower than the first voltage.

15. A radio frequency (RF) switch circuit comprising:
a first switch connected between a first port and an antenna port;
a second switch connected between a second port and the antenna port;
a third switch connected between the antenna port and ground;
a fourth switch connected between the antenna port and the ground; and
a switch control circuit configured to control the first switch, the second switch, and the third switch to be turned off using a first power source and the fourth switch to be turned on using a second power source different from the first power source in a low power mode.

16. The RF switch circuit of claim 15, wherein the switch control circuit is configured to turn off the first switch, the second switch, and the fourth switch and turn on the third switch using the first power source in an isolation mode.

17. The RF switch circuit of claim 15, wherein the switch control circuit is configured to turn on the first switch and turn off the second switch, the third switch, and the fourth switch using the first power source in a reception mode.

18. The RF switch circuit of claim 15, wherein the switch control circuit is configured to turn on the second switch and turn off the first switch, the third switch, and the fourth switch using the first power source in a transmission mode.

19. The RF switch circuit of claim 15, wherein the switch control circuit comprises:
a first driver configured to select one of a first voltage and a second voltage generated from the first power source according to a first control signal and output the selected voltage to the first switch;
a second driver configured to select one of the first voltage and the second voltage according to the first control signal and output the selected voltage to the second switch;
a third driver configured to select one of the first voltage and the second voltage according to the first control signal and output the selected voltage to the third switch; and
a fourth driver configured to output one of a third voltage generated from the second power source and a fourth voltage generated from the first power source to the fourth switch according to a second control signal.
